(19) United States
(12) Patent Application Publication
(10) Pub. No.: US 2026/0348004 A1
(43) Pub. Date: Nov. 5, 2026

(54) SEMICONDUCTOR PROCESSING SYSTEMS FOR PERFORMING IN-SITU CLEANING AND ASSOCIATED METHODS

(71) Applicant: ASM IP Holding B.V., Almere (NL)

(72) Inventors: Shahram Ghanad Tavakoli, Chandler, AZ (US); Amir Kajbafvala, Chandler, AZ (US)

(21) Appl. No.: 19/659,260

(22) Filed: Apr. 27, 2026

Related U.S. Application Data
(60) Provisional application No. 63/797,875, filed on Apr. 30, 2025.

(51) Int. Cl. C23C 16/44; H01J 37/32

(52) U.S. Cl. CPC C23C 16/4405; H01J 37/3211; H01J 37/32862; H01J 2237/3321

(57) ABSTRACT

Semiconductor processing systems for performing in-situ cleaning are disclosed. The semiconductor processing system includes a reaction chamber and a gas delivery assembly. The gas delivery assembly is connected to the reaction chamber and includes a gas source, a gas conduit, and an inductively coupled plasma generator. The gas conduit includes a first segment connected to the gas source and made of stainless steel and a second segment adjacent to the first segment and made of quartz material. The inductively coupled plasma generator is coupled to the second segment of the gas conduit and configured to provide the reactive species to the reaction chamber for performing in-situ cleaning.

### CROSS-REFERENCE TO RELATED APPLICATIONS

This application is a nonprovisional of, and claims priority to and the benefit of, U.S. Provisional Patent Application No. 63/797,875, filed Apr. 30, 2025 and entitled “SEMICONDUCTOR PROCESSING SYSTEMS FOR PERFORMING IN-SITU CLEANING AND ASSOCIATED METHODS,” which is hereby incorporated by reference herein.

### FIELD

The present disclosure generally relates to the field of semiconductor processing systems. More particularly, the present disclosure relates to semiconductor processing systems configured to perform in-situ cleaning and associated methods for surface cleaning.

### BACKGROUND

The quality of an epitaxial layer is critically dependent on the cleanliness of the initial substrate surface. Conventional surface cleaning techniques may be performed at elevated temperatures, such as approximately 1050 °C. However, such high-temperature approaches may require high energy consumption, and they may exceed the thermal budget of certain materials on the substrate, thereby causing undesirable effects such as instability, increased surface roughness, and/or damage to the substrate and the layers grown on it. In addition, with increasingly stringent device requirements, epitaxial layers are required to be grown at lower temperatures, typically below 800 °C. This reduced thermal budget imposes a significant limitation on the effectiveness of substrate surface cleaning.

Any discussion, including discussion of problems and solutions set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In an aspect, various embodiments provided include a semiconductor processing system comprising a reaction chamber and a gas delivery assembly. The gas delivery assembly is connected to the reaction chamber and includes a gas source, a gas conduit, and an inductively coupled plasma generator. The gas conduit includes a first segment connected to the gas source and made of stainless steel and a second segment adjacent to the first segment and made of quartz material. The inductively coupled plasma generator is coupled to the second segment of the gas conduit and configured to provide the reactive species to the reaction chamber for performing in-situ cleaning.

In some embodiments, the reaction chamber is an epitaxial reaction chamber configured for depositing epitaxial layers of a material.

In some embodiments, the gas source comprises nitrogen (N₂), hydrogen (H₂), halogen, or a combination thereof.

In some embodiments, the gas source comprises chlorine (Cl₂) and nitrogen (N

In some embodiments, the reactive species include nitrogen ions, nitrogen radicals, excited species of nitrogen, hydrogen ions, hydrogen radicals, excited species of hydrogen, halogen ions, halogen radicals, excited species of halogen, or a combination thereof. In some embodiments, the reactive species comprises chlorine ions, chlorine radicals, and excited species of chlorine.

In some embodiments, the inductively coupled plasma generator comprises an induction coil and an RF power supply and matching network. The induction coil is coupled to and wound around the second segment. The RF power supply and matching network are electrically connected to the induction coil and configured to flow an energizing current through the induction coil to energize a cleaning gas from the gas source into the reactive species.

In some embodiments, the gas conduit further comprises a third segment adjacent to the second segment and connected to the reaction chamber, wherein the third segment comprises stainless steel lined with an insulating coating.

In some embodiments, the third segment has a shorter length than the first segment.

In some embodiments, the insulating coating comprises at least one of polytetrafluoroethylene (PTFE), fluorinated ethylene propylene copolymer (FEP), perfluoroalkoxy (PFA), polyethylene terephthalate copolymer (PETG), and polyamide-based copolymers.

In some embodiments, the epitaxial reaction chamber comprises a quartz assembly including an upper wall and a lower wall, the upper wall extending longitudinally between an injection chamber flange and a longitudinally opposite exhaust chamber flange, the lower wall being below and parallel relative to the upper wall, and a substrate support positioned within the epitaxial reaction chamber and configured to support a substrate.

In an aspect, various embodiments provided include a surface cleaning method comprising providing a reaction chamber; and supplying a cleaning gas through a gas conduit, wherein the gas conduit comprises: a first segment connected to a gas source and made of stainless steel, and a second segment adjacent to the first segment and made of quartz material. The method further comprises generating a reactive species from the cleaning gas using an inductively coupled plasma generator coupled to the second segment of the gas conduit; and introducing the reactive species into the reaction chamber to perform in-situ cleaning.

In some embodiments, the reaction chamber is an epitaxial reaction chamber configured for depositing epitaxial layers of a material.

In some embodiments, the method further comprises positioning a substrate on a substrate support arranged within the epitaxial reaction chamber before generating the reactive species, wherein the in-situ cleaning comprises removing a surface layer on the substrate.

In some embodiments, the in-situ cleaning comprises formation of volatile silicon chloride species.

In some embodiments, the in-situ cleaning removes parasitic deposition on interior walls of the epitaxial reaction chamber.

In some embodiments, the interior walls of the epitaxial reaction chamber are made of quartz material.

In some embodiments, a temperature of the in-situ cleaning is between 300 °C and 800 °C.

In some embodiments, the method further comprises, after the in-situ cleaning: introducing a precursor into the epitaxial reaction chamber for performing epitaxial deposition.

In some embodiments, generating a reactive species from the cleaning gas comprises coupling an induction coil of the inductively coupled plasma generator to the second segment; and flowing an energizing current through the induction coil to energize the cleaning gas into the reactive species by an RF power supply and matching network electrically connected to the induction coil.

In some embodiments, the reactive species is introduced into the epitaxial reaction chamber through a third segment adjacent to the second segment of the gas conduit, wherein the third segment comprises stainless steel lined with an insulating coating.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a cross-sectional view of a semiconductor processing system in accordance with one or more embodiments.

FIG. 2 is a cross-sectional view illustrating the arrangement of a gas delivery assembly and an inductively coupled plasma generator in accordance with one or more embodiments.

FIGS. 3A to 3C are schematic diagrams illustrating various stages of a surface cleaning process in accordance with one or more embodiments.

FIG. 4 is a flow chart illustrating an example of a surface cleaning method.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Fabrication of integrated circuits often can involve formation of one or more material layers on a substrate surface. These material layers can include, for example, mono-crystalline, polycrystalline, and/or amorphous material layers. Formation of the material layers can be achieved using various thin film deposition techniques, including various physical (e.g., physical sputtering) and/or chemical (e.g., chemical vapor deposition, atomic layer deposition, and/or epitaxial deposition) deposition techniques. For example, mono-crystalline material formation on a substrate surface can be performed using an epitaxial deposition process, such as for formation of mono-crystalline semiconductor materials (e.g., mono-crystalline silicon).

The presence of unwanted material (e.g., native oxide, residue from upstream processing, and/or other contaminants) on the substrate surface may interfere with formation of a desired material layer over that substrate surface. For example, the intervening material may introduce an increased number of structural defects in the desired layer and/or degrade its electrical performance.

In some embodiments, an intervening material such as native oxide may form on a substrate surface due to exposure of the substrate to oxygen during the integrated circuit fabrication process (e.g., exposure to ambient air during transfer of the substrate between fabrication systems, and/or to residual oxidizing agents within fabrication systems). The removal of such unwanted material may be time-consuming and may adversely affect process throughput. Accordingly, there remains a need for methods and systems capable of removing unwanted material from the substrate surface while minimizing negative impacts on throughput. The present disclosure addresses this need.

Various embodiments relate to semiconductor processing systems configured to perform a low-temperature in-situ cleaning by using a gas conduit that includes a segment made of quartz material coupled to an inductively coupled plasma (ICP) generator for generating reactive species. The present disclosure also provides surface cleaning methods employing the semiconductor processing systems. The semiconductor processing systems may be used to clean a surface of a substrate, such as a semiconductor wafer. In addition, the semiconductor processing systems may be employed to clean interior walls of reaction chambers. By way of example, the reaction chambers described herein can be used to form or grow material layers (e.g., epitaxial layers) on the surface of the substrate.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride, and silicon carbide, for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of example, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

The terms precursor gas and/or precursor gases may refer to a gas or combination o f gases that participate in a chemical reaction that produces another compound. For example, precursor gases may be used to grow an epitaxial layer comprising silicon germanium. Precursor gases may include a deposition gas or gases, a dopant gas or gases, or a combination of a deposition gas or gases and a dopant gas or gases. The precursor gases may include a silicon precursor such as a high-order silicon precursor. The silicon precursor may further include silane (SiH₄) or silicon tetrachloride (SiCl₄). In some examples, the silicon precursor may have one silicon atom per molecule, such as silane. The high-order silicon precursor may have two or more silicon atoms per molecule, such as disilane. In some examples, the high-order silicon precursors may have three or more silicon atoms. The high-order silicon precursors may include a non-halogenated high-order silicon precursor, such as trisilane and tetrasilane. The high-order silicon precursor may include a halogenated high-order silicon precursor, for example, a high-order chlorine-containing precursor, such as chlorodisilane, dichlorosilane, trichlorosilane, and tetrachlorosilane. The precursor gases may include a high-order germanium-containing material layer precursor, such as germane, digermane, trigermane, their chloride derivatives and mixtures thereof. The precursor gases may include a p-dopant high-order precursor such as diborane (B₂H₆). The precursor gases may also include an n-dopant high-order precursor such as phosphine (PH₃) and arsine (AsH₃).

As used herein, the term “epitaxial layer” can refer to a single crystalline layer (or substantially single crystalline layer) directly on an underlying single crystalline (or substantially single crystalline) substrate or layer.

As used herein, the term “reactive species” may refer to one or more species generated by the plasma excitation of a gas (including gas mixtures) and may include, but is not limited to, ions, radicals, and excited species.

In the following description of the various embodiments, reference is made to the accompanying drawings, which form a part hereof, and in which is shown by way of illustration various embodiments in which aspects of the disclosure may be practiced. It is to be understood that other embodiments may be utilized, and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

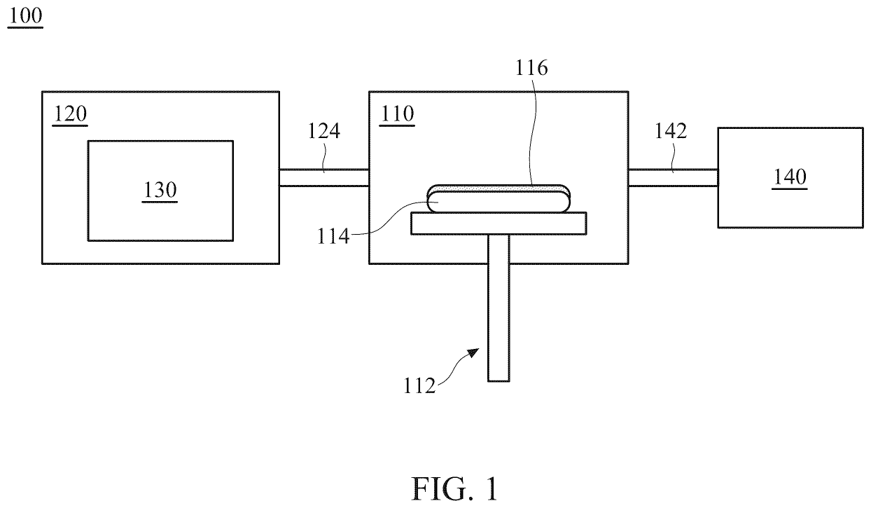

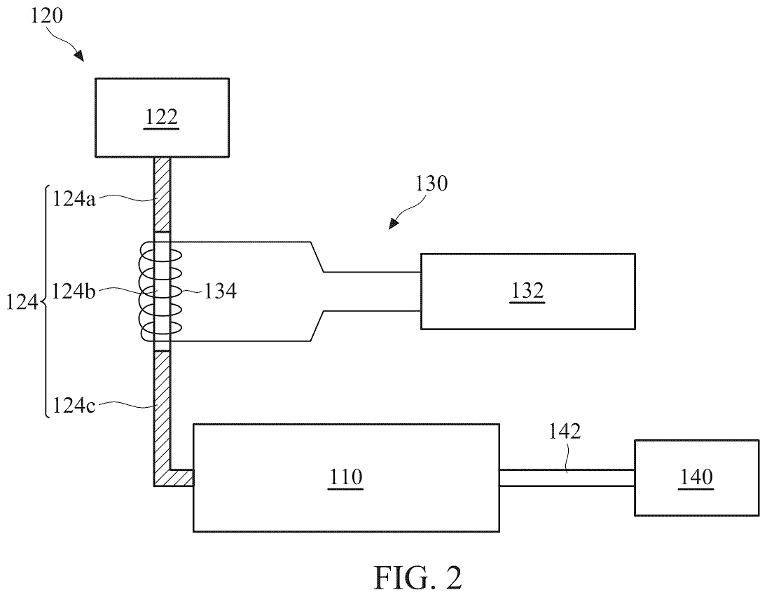

FIG. 1 illustrates a cross-sectional view of a semiconductor processing system 10 in accordance with one or more embodiments of the disclosure. FIG. 2 is a cross-sectional view illustrating the arrangement of a gas delivery assembly 120 and an inductively coupled plasma generator 130 in accordance with one or more embodiments of the disclosure.

As shown in FIG. 1, the semiconductor processing system 100 includes a reaction chamber 110. The reaction chamber 110 may be an epitaxial reaction chamber configured for depositing epitaxial layers of a material.

The reaction chamber 110 may include a substrate support 112 positioned within the reaction chamber 110 and configured to support a substrate 114. In some embodiments, a surface layer 116 is formed on the substrate 114. The surface layer 116 may be a surface oxide (e.g., a native oxide), a nitride, a carbon, a carbide film, or the like. The substrate support 112 may include a shaft member arranged within the reaction chamber 110 and configured for rotating the substrate 114. The substrate support 112 may be formed from an opaque material, such as silicon carbide or a bulk graphite material. Although a specific arrangement is shown and described herein, it is to be understood and appreciated that the arrangement of the reaction chamber 110 may include other elements and/or omit certain depicted elements while remaining within the scope of the present disclosure.

The semiconductor processing system 100 also includes a gas delivery assembly 120 connected to the reaction chamber 110. The gas delivery assembly 120 is constructed and arranged to provide a vapor phase process gas to the reaction chamber 110. The gas delivery assembly 120 includes a gas conduit 124, which fluidly connects the gas delivery assembly 120 to the reaction chamber 110. The vapor phase process gas may include a single gas or a mixture of gases including, but not limited to, cleaning gases, precursor gases, dopant gases, etchant gases, and inert gases (e.g., purge gases, carrier gases). The gas delivery assembly 120 may include various systems, sub-systems, and components (not shown) for generating and controlling the flow of the vapor phase process gas, from the sources to the gas conduit 124.

The gas delivery assembly 120 also includes an inductively coupled plasma (ICP) generator 130 positioned therein. The inductively coupled plasma generator 130 is configured to provide reactive species (e.g., from a plasma) to the reaction chamber 110 for performing the low-temperature in-situ cleaning, as described in detail below.

The semiconductor processing system 100 also includes an exhaust port 140 and an exhaust conduit 142 connected between the reaction chamber 110 and the exhaust port 140. The exhaust port 140 may be configured to evacuate the reaction chamber 110 through the exhaust conduit 142. In some embodiments, the exhaust port 140 may include one or more vacuum pumps (not shown) and an abatement system (not shown). The vacuum pumps can be connected to the reaction chamber 110 and configured to control the pressure within the chamber interior. The abatement system can be connected to the one or more vacuum pumps and be configured to process the flow of residual precursor and/or reaction products issued from the reaction chamber 110. In some embodiments, the exhaust port 140 may be configured to maintain environmental conditions within the chamber interior suitable for process operations. In an example, the exhaust port 140 is configured to maintain environmental conditions within the chamber interior suitable for extending the lifetimes of the reactive species generated by the inductively coupled plasma generator 130.

As shown in FIG. 2, the gas delivery assembly 120 also includes a gas source 122. The gas source 122 may include the aforementioned vapor phase process gas. In some embodiments, the gas source 122 includes a cleaning gas source including one or more cleaning gases. The cleaning gases provided by the gas source 122 are introduced into the gas conduit 124. In some embodiments, the cleaning gases may include nitrogen (N₂), hydrogen (H₂), a halogen (e.g., chlorine, fluorine, bromine, iodine), or a combination thereof. In an exemplary embodiment, the cleaning gases include a halogen, such as chlorine (Cl₂). In another exemplary embodiment, the cleaning gases include chlorine (Cl₂) and nitrogen (N₂).

In some embodiments, the gas conduit 124 includes a first segment 124a and a second segment 124b. In some embodiments, the first segment 124a is connected to the gas source 122 and configured to deliver the cleaning gases provided by the gas source 122. The second segment 124b is adjacent to and connected with the first segment 124a, and forms a portion of the gas conduit 124 coupled to the inductively coupled plasma generator 130. In some embodiments, the first segment 124a is made of stainless steel, and the second segment 124b is made of quartz material.

In some embodiments, the inductively coupled plasma generator 130 may include an RF power supply and matching network 132 and an induction coil 134. The induction coil 134 is coupled to and wound around the second segment 124b of the gas conduit 124. The RF power supply and matching network 132 is electrically connected to the induction coil 134 and configured to flow an energizing current through the induction coil 134 to energize a cleaning gas from the gas source 122 into the reactive species. In some embodiments, the reactive species includes nitrogen ions (e.g., N⁺, N₂⁺) , nitrogen radicals (e.g., N*), excited species of nitrogen, hydrogen ions (e.g., H⁺, H₂⁺, H₃⁺), hydrogen radicals (e.g., H*), excited species of hydrogen, halogen ions, halogen radicals, excited species of halogen, or a combination thereof. In an exemplary embodiment, the reactive species includes halogen ions, halogen radicals, and/or excited species of halogen. For example, the reactive species includes chlorine ions (e.g., Cl⁺, Cl₂⁺), chlorine radicals (e.g., Cl*), and/or excited species of chlorine. As used herein, the term “matching network” can refer to an element employed for adjusting the impedance between the power supply and the plasma load to ensure efficient power transfer and stable plasma conditions in the reaction chamber. In addition, the inductively coupled plasma generator 130 may include various sensors and monitoring systems to assess the plasma state and/or the generation of reactive species.

In some embodiments, the gas conduit 124 also includes a third segment 124c adjacent to the second segment 124b and connected to the reaction chamber 110. That is, the third segment 124c is connected between the second segment 124b and the reaction chamber 110. In some embodiments, the cleaning gases provided by the gas source 122 are delivered from the first segment 124a to the second segment 124b. As the cleaning gases pass through the second segment 124b, they are energized by the inductively coupled plasma (ICP) generator 130 to form reactive species. The reactive species are then delivered to the reaction chamber 110 through the third segment 124c. In some embodiments, the third segment 124c has a shorter length than the first segment 124a, which helps prevent recombination of the reactive species and ensures their integrity during transport. In some embodiments, the third segment 124c includes stainless steel lined with an insulating coating, which helps prolong the lifetimes of the reactive species. In some embodiments, the insulating coating may include at least one of polytetrafluoroethylene (PTFE), fluorinated ethylene propylene copolymer (FEP), perfluoroalkoxy (PFA), polyethylene terephthalate copolymer (PETG), and polyamide-based copolymers.

Various embodiments provided include methods for surface cleaning employing the semiconductor processing systems previously described. The following describes an exemplary embodiment of the surface cleaning method according to the present disclosure.

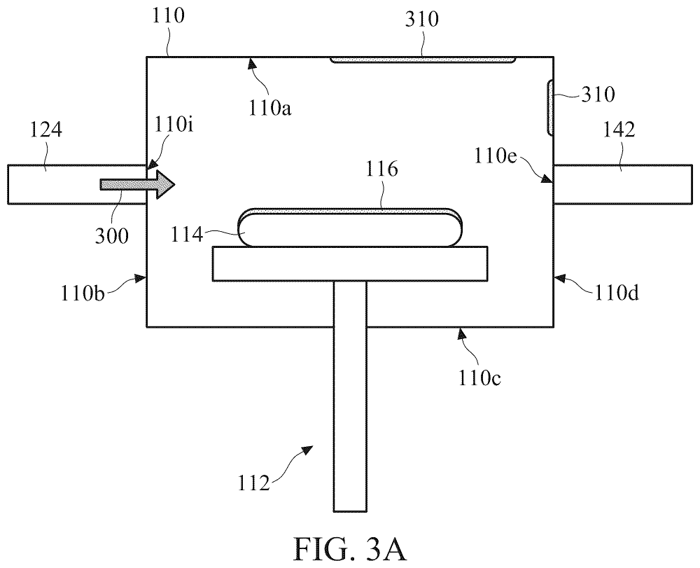

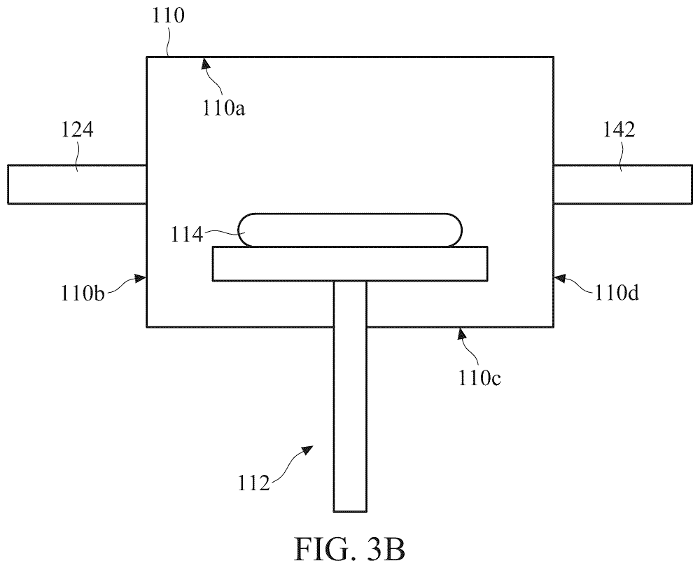

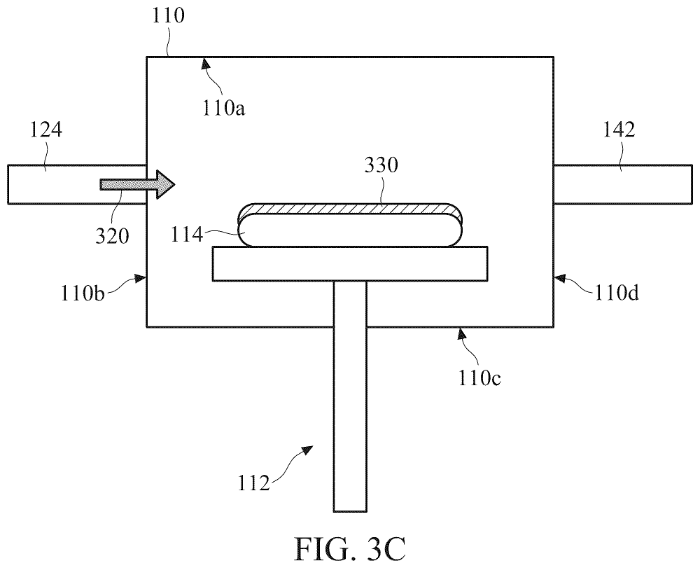

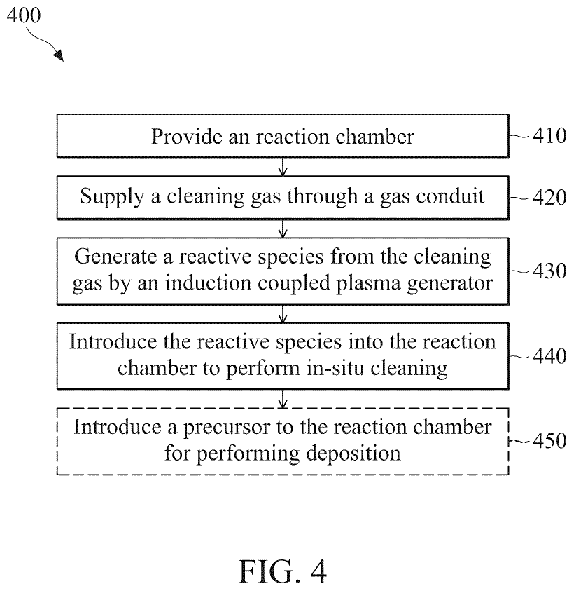

FIGS. 3A to 3C are schematic diagrams illustrating various stages of a surface cleaning process in accordance with one or more embodiments. FIG. 4 is a flow chart illustrating an example of a surface cleaning method 400. In an example, the surface cleaning method 400 will be described with reference to FIGS. 3A to 3C.

Referring to FIG. 3A in conjunction with FIG. 4, the method 400 may begin at block 410, where a reaction chamber (e.g., the reaction chamber 110) is provided. In some embodiments, the reaction chamber 110 has interior walls which may be formed from a quartz material. In certain embodiments, the reaction chamber 110 may include a quartz assembly including an upper wall 110a, a first side wall 110b, a lower wall 110c, and a second side wall 110d opposing the first side wall 110b. The reaction chamber 110 may have an injection end positioned adjacent to the first side wall 110b and a longitudinally opposite exhaust end positioned adjacent to the second side wall 110d. The reaction chamber 110 may further include an injection chamber flange 110i configured to fluidly couple the gas conduit 124 and the injection end, and an exhaust chamber flange 110e configured to fluidly couple the exhaust end and the exhaust conduit 142. The upper wall 110a extends longitudinally between the injection chamber flange 110i and the longitudinally opposite exhaust chamber flange 110e. The lower wall 110c is below and parallel relative to the upper wall 110a.

The substrate 114 is provided and supported by the substrate support 112. I some embodiments, the substrate support 112 can be positioned between the injection chamber flange 110i and the exhaust chamber flange 110e of the reaction chamber 110. In some embodiments, the substrate 114 has the surface layer 116 (such as a native oxide) thereon. In some embodiments, parasitic deposition 310 may also form on the interior walls of the reaction chamber 110. In some cases, the parasitic deposition 310 may refer to the unwanted deposition of materials in non-target areas or in undesirable forms during semiconductor processing, such as chamber coating, which may flake off and cause particles or defects in the processed semiconductor device. This can occur during both deposition and etching processes. Although the parasitic deposition 310 is illustrated as forming on the upper wall 110a and the second side wall 110d in FIG. 3A, it is to be understood that the parasitic deposition 310 may occur at any location within the reaction chamber shown or described herein, without departing from the scope of the present disclosure. In some embodiments, the parasitic deposition may comprise an oxide (e.g., a native oxide), a nitride, a phosphide, a carbon material, and/or mixtures thereof. In some embodiments, the parasitic deposition may comprise an amorphous layer, a crystalline layer, a polycrystalline layer, or mixtures thereof. In some embodiments, the parasitic deposition may comprise a semiconductor material selected from silicon, silicon germanium, germanium, and III-V semiconducting materials.

The method 400 may continue at block 420, where a cleaning gas is supplied through a gas conduit (e.g., gas conduit 124). As described above, the cleaning gas may be supplied from the gas source (e.g., gas source 122 in FIG. 2). In some embodiments, the cleaning gas may include nitrogen (N₂), hydrogen (H₂), halogen (e.g., chlorine, fluorine, bromine, iodine), or a combination thereof. In an exemplary embodiment, the cleaning gas includes halogen, such as chlorine (Cl₂). In another exemplary embodiment, the cleaning gas includes chlorine (Cl₂) and nitrogen (N₂).

At block 430, reactive species may be generated in a plasma. In some embodiments, the reactive species may be generated from the cleaning gas by an inductively coupled plasma (ICP) generator (e.g., inductively coupled plasma generator 130 in FIG. 2). In some embodiments, the method of generating the reactive species from the cleaning gas by the inductively coupled plasma generator includes: coupling an induction coil (e.g., induction coil 134 in FIG. 2) of the inductively coupled plasma generator to the gas conduit (e.g., second segment 124b of gas conduit 124 in FIG. 2); and flowing an energizing current through the induction coil to energize the cleaning gas into the reactive species by an RF power supply and matching network (e.g., RF power supply and matching network 132 in FIG. 2) electrically connected to the induction coil. In certain embodiments, the cleaning gas may be supplied at a flow rate of about 0.5 to about 10000 sccm, under a pressure ranging from about 0.01 to about 600 Torr, and the ICP RF power can be set in the range of about 300 to about 4000 W.

In some embodiments, the reactive species includes nitrogen ions (e.g., N⁺, N₂⁺), nitrogen radicals (e.g., N*), excited species of nitrogen, hydrogen ions (e.g., H⁺, H₂⁺, H₃⁺), hydrogen radicals (e.g., H*), excited species of hydrogen, halogen ions, halogen radicals, excited species of halogen, or a combination thereof. In the case where chlorine (Cl₂) is used as the cleaning gas, the reactive species may include chlorine ions (e.g., Cl⁺, Cl₂⁺) , chlorine radicals (e.g., Cl*), and/or excited species of chlorine.

At block 440, the reactive species is introduced into the reaction chamber to perform in-situ cleaning. In some embodiments, as shown in FIG. 3A, the reactive species is introduced into the interior of the reaction chamber 110 (e.g., as indicated by process gas flow 300) through the injection chamber flange 110i. In some embodiments, the reactive species may be supplied at a flow rate of about 0.5 to about 10000 sccm, under a chamber pressure ranging from about 0.01 to about 600 Torr. In some embodiments, the in-situ cleaning is performed at a temperature below 800 °C, below 600 °C, below 500 °C, below 400 °C, below 300 °C, below 200 °C, below 150 °C, or between 150 °C and 800 °C For example, the in-situ cleaning is performed at a temperature ranging from approximately 150 °C to 800 °C, or from approximately 300 °C to 500 °C. Accordingly, in-situ cleaning may be carried out at a low temperature without causing damage to the layers or devices formed on the substrate. After introducing the reactive species into the interior of the reaction chamber 110, the reactive species may contact the surface layer 116 on the substrate 114 and/or the parasitic deposition 310 on the interior walls of the reaction chamber 110. Subsequently, the reactive species may react with the surface layer 116 and/or the parasitic deposition 310, thereby removing the unwanted material or layers.

In some embodiments, the in-situ cleaning may include formation of volatile species. For example, the in-situ cleaning may include the following steps: contacting the reactive species (e.g., chlorine radicals and/or chlorine ions) on the surface layer 116 (e.g., native oxide); forming an interface layer (not shown) from the top of the surface layer 116; releasing volatile species and thinning the surface layer 116; and etching the substrate 114. Afterward, the surface layer 116 can be removed from the substrate 114. In some embodiments, the interface layer may include silicon chloride (SiClₓ), silicon fluoride (SiFₓ), silicon bromide (SiBrₓ), or any halogen related compound. In the case where the reactive species includes chlorine ions and/or chlorine radicals, the volatile species may include volatile silicon chloride species.

As shown in FIG. 3B, after performing the in-situ cleaning process, the unwanted material or layers are removed, leaving a pristine and clean substrate 114. As such, this may help minimize or reduce the negative impacts of unwanted layers or their interfaces on the subsequent deposition on the substrate, thereby improving film growth quality, preventing crystallographic defect formation, and achieving high yield. In addition, the removal of unwanted material or layers can improve the quality of an epitaxial layer or layer stack (e.g., comprising two or more layers) on the substrate.

In some embodiments, the method 400 may optionally perform block 450, which is illustrated as a dashed box in FIG. 4. Referring to FIG. 3C in conjunction with FIG. 4, at block 450, after the in-situ cleaning process (block 440), the method 400 may optionally include introducing one or more precursor gases (such as silicon precursor, germanium-containing material layer precursor, p-dopant high-order precursor, n-dopant high-order precursor, or a combination thereof) into the reaction chamber 110, as shown by the process gas flow 320, to perform epitaxial deposition. Subsequently, an epitaxial layer 330 may be formed on the substrate 114. Conventional techniques may be used to form the epitaxial layer 330, and the details are omitted herein for brevity.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing system, comprising:
a reaction chamber; and
a gas delivery assembly connected to the reaction chamber and comprising:
a gas source;
a gas conduit comprising:
a first segment connected to the gas source and made of stainless steel; and
a second segment adjacent to the first segment and made of quartz material; and
an inductively coupled plasma generator coupled to the second segment of the gas conduit and configured to provide reactive species to the reaction chamber for performing in-situ cleaning.

2. The semiconductor processing system of claim 1, wherein the reaction chamber is an epitaxial reaction chamber configured for depositing epitaxial layers of a material.

3. The semiconductor processing system of claim 1, wherein the gas source comprises nitrogen (N₂), hydrogen (H₂), halogen, or a combination thereof.

4. The semiconductor processing system of claim 3, wherein the gas source comprises chlorine (Cl₂) and nitrogen (N₂).

5. The semiconductor processing system of claim 4, wherein the reactive species comprises chlorine ions, chlorine radicals, and excited species of chlorine.

6. The semiconductor processing system of claim 1, wherein the inductively coupled plasma generator comprises:
an induction coil coupled to and wound around the second segment; and
an RF power supply and matching network electrically connected to the induction coil and configured to flow an energizing current through the induction coil to energize a cleaning gas from the gas source into the reactive species.

7. The semiconductor processing system of claim 1, wherein the gas conduit further comprises a third segment adjacent to the second segment and connected to the reaction chamber, wherein the third segment comprises stainless steel lined with an insulating coating.

8. The semiconductor processing system of claim 7, wherein the third segment has a shorter length than the first segment.

9. The semiconductor processing system of claim 8, wherein the insulating coating comprises at least one of polytetrafluoroethylene (PTFE), fluorinated ethylene propylene copolymer (FEP), perfluoroalkoxy (PFA), polyethylene terephthalate copolymer (PETG), and polyamide-based copolymers.

10. The semiconductor processing system of claim 2, wherein the epitaxial reaction chamber comprises a quartz assembly including an upper wall and a lower wall, the upper wall extending longitudinally between an injection chamber flange and a longitudinally opposite exhaust chamber flange, the lower wall being below and parallel relative to the upper wall, and a substrate support positioned within the epitaxial reaction chamber and configured to support a substrate.

11. A surface cleaning method, comprising:
providing a reaction chamber;
supplying a cleaning gas through a gas conduit, wherein the gas conduit comprises:
a first segment connected to a gas source and made of stainless steel; and
a second segment adjacent to the first segment and made of quartz material;
generating a reactive species from the cleaning gas using an inductively coupled plasma generator coupled to the second segment of the gas conduit; and
introducing the reactive species into the reaction chamber to perform in-situ cleaning.

12. The surface cleaning method of claim 11, wherein the reaction chamber is an epitaxial reaction chamber configured for depositing epitaxial layers of a material.

13. The surface cleaning method of claim 12, further comprising:
positioning a substrate on a substrate support arranged within the epitaxial reaction chamber before generating the reactive species, wherein the in-situ cleaning comprises removing a surface layer on the substrate.

14. The surface cleaning method of claim 13, wherein the in-situ cleaning comprises formation of volatile silicon chloride species.

15. The surface cleaning method of claim 12, wherein the in-situ cleaning removes parasitic deposition on interior walls of the epitaxial reaction chamber.

16. The surface cleaning method of claim 15, wherein the interior walls of the epitaxial reaction chamber are made of quartz material.

17. The surface cleaning method of claim 11, wherein a temperature of the in-situ cleaning is between 300 °C and 800 °C.

18. The surface cleaning method of claim 11, further comprising, after the in-situ cleaning:
introducing a precursor into the reaction chamber for performing epitaxial deposition.

19. The surface cleaning method of claim 11, wherein generating a reactive species from the cleaning gas comprises:
coupling an induction coil of the inductively coupled plasma generator to the second segment; and
flowing an energizing current through the induction coil to energize the cleaning gas into the reactive species by an RF power supply and matching network electrically connected to the induction coil.

20. The surface cleaning method of claim 12, wherein the reactive species is introduced into the epitaxial reaction chamber through a third segment adjacent to the second segment of the gas conduit, wherein the third segment comprises stainless steel lined with an insulating coating.
